(19) United States
(12) Patent Application Publication
(10) Pub. No.: US 2018/0069394 A1
(43) Pub. Date: Mar. 8, 2018

(54) POWER-LIMIT PROTECTION CIRCUIT WITH AN EFUSE ELEMENT

(71) Applicant: Monolithic Power Systems, Inc., San Jose, CA (US)

(72) Inventors: Mark Hagen, Rochester, MN (US); Brent Hughes, Cumming, GA (US); Karl Kopp, Whitmore Lake, MI (US); Jason Pierce, Dahlonega, GA (US)

(21) Appl. No.: 15/257,840

(22) Filed: Sep. 6, 2016

(51) Int. Cl. H02H 9/00; H02H 5/04; G01R 21/06; G01R 21/133

(52) U.S. Cl. CPC H02H 9/00; G01R 21/133; G01R 21/06; H02H 5/047

(57) ABSTRACT

A power-limit protection circuit with an efuse element. The power-limit protection circuit has an efuse element coupled between a first terminal and a second terminal. The power-limit protection circuit judges whether a calculated power signal defined from a current signal flowing through the efuse element and a voltage signal at a terminal of the efuse element is larger than a predetermined power threshold. When the calculated power signal is larger than the predetermined power threshold, the power-limit protection circuit increases an impedance of the efuse element to limit the current signal between the first terminal and the second terminal such that the power delivered through the efuse element is limited within the predetermined power threshold.

### TECHNICAL FIELD

The present invention generally relates to electronic circuit, and more particularly but not exclusively relates to a power-limit protection circuit with an efuse element and associated method.

### BACKGROUND

Electronic systems often require protection function to ensure that these systems will function in a safe environment when an over current condition or an over voltage condition occurs.

Due to a quick and precise response, electrically programmable fuse (efuse) element is widely used in a protection circuit for protecting a system. Generally, an efuse element comprises a controlled Field Effect Transistor (FET), e.g. MOSFET. In prior art, we often control an efuse element based on a current signal flowing through it. For example, when the system operates normally (i.e., no over-current condition occurs), the efuse element is fully turned on. If the current signal flowing through the efuse element is larger than a predetermined current value, the efuse element operates in a variable resistance region and functions to increase its impedance between its source and drain so as to limit the current signal. If the current signal continues to increase, the impedance of the efuse element keeps increasing and finally enters into a constant-current region (i.e., the impedance of the efuse element is ideally infinite, thus, the current signal flowing through the efuse element is limited to the predetermined current value for protecting the whole system. After the current signal is limited, the voltage across the efuse element will rise, which will cause the power dissipated in the efuse element to rise. So in practice, the efuse element may quickly hit a thermal protection threshold and be turned off.

For example, FIG. 1 illustrates a prior art current-limit protection circuit 50 with an efuse element. As shown in FIG. 1, the current-limit protection circuit 50 comprises an efuse element 51 coupled between a first terminal TRML1 and a second terminal TRML2. A current signal Ie flows through the efuse element 51 from the first terminal TRML1 to the second terminal TRML2. The current-limit protection circuit 50 further comprises a current sense circuit 52 configured to sense the current signal Ie to generate a sensed current signal I_{S}. The current-limit protection circuit 50 also comprises a controller 53. The controller 53 is configured to receive the sensed current signal I_{S} and further configured to provide a control signal C_{GATE} to a gate of the efuse element 51. When the sensed current signal I_{S} is larger than a predetermined current value, the efuse element 51 is controlled by the control signal C_{GATE} to increase its impedance sufficiently to limit the current signal Ie that flows from the first terminal TRML1 to the second terminal TRML2.

However, controlling efuse element only based on a current signal will bring more inconvenience. For example, an over output current threshold of 5A is set for an application at a rated power 15 W. For this application, the output voltage should be limited to 3V maximum for a system protection. However, in a voltage converter, the output voltage can be changed based on different loads. If the output voltage is changed to be higher than 3V, e.g., 4V, an over output current threshold of 5A cannot ensure an over current protection at a rated power of 15 W. The over output current threshold should be changed, e.g. to 3.75 A. However, it is inconvenient for reprogramming the over output current threshold at different output voltage values.

Thus, it is desired to have a more efficient protection circuit.

### SUMMARY

Embodiments of the present invention are directed to a power-limit protection circuit, comprising: an efuse element, coupled between a first terminal and a second terminal; a current sense circuit, configured to sense a current signal flowing through the efuse element to generate a sensed current signal; a voltage sense circuit, configured to sense a voltage signal at the second terminal to generate a sensed voltage signal; and a controller, configured to receive the sensed current signal and the sensed voltage signal, to define a calculated power signal from the sensed current signal and the sensed voltage signal, and to judge whether a calculated power signal is larger than a predetermined power threshold, when the calculated power signal is larger than the predetermined power threshold, the controller is configured to increase impedance of the efuse element to limit the current flowing from the first terminal to the second terminal.

Embodiments of the present invention are further directed to a power-limit protection method with an efuse element, wherein the efuse element is coupled between a first terminal and a second terminal. The power-limit protection method comprises: turning the efuse element on fully; sensing the current signal flowing through the efuse element; sensing a voltage signal at the first terminal or the second terminal of the efuse element; judging whether a calculated power signal is larger than a predetermined power threshold; and increasing impedance of the efuse element to limit the current between the first terminal and the second terminal when the calculated power signal is larger than the predetermined power threshold.

### BRIEF DESCRIPTION OF THE DRAWINGS

Non-limiting and non-exhaustive embodiments are described with reference to the following drawings. The drawings are only for illustration purpose. Usually, the drawings only show part of the system or circuit of the embodiment, and the same reference label in different drawings have the same, similar or corresponding features or functions.

FIG. 1 illustrates a prior art current-limit protection circuit with an efuse element 50.

FIG. 2 illustrates a power-limit protection circuit 100 with an efuse element in accordance with an embodiment of the present invention.

FIG. 3 schematically illustrates a power-limit protection circuit 200 with an efuse element according to an embodiment of the present invention.

FIG. 4 schematically illustrates a power-limit protection circuit 300 with an efuse element according to an embodiment of the present invention.

FIG. 5 illustrates a power-limit protection method 400 with an efuse element in accordance with an embodiment of the present invention.

FIG. 6 illustrates a converter system 500 with a plurality of power-limit protection circuits according to an embodiment of the present invention.

FIG. 7 illustrates a converter system 600 with a plurality of power-limit protection circuits according to an embodiment of the present invention.

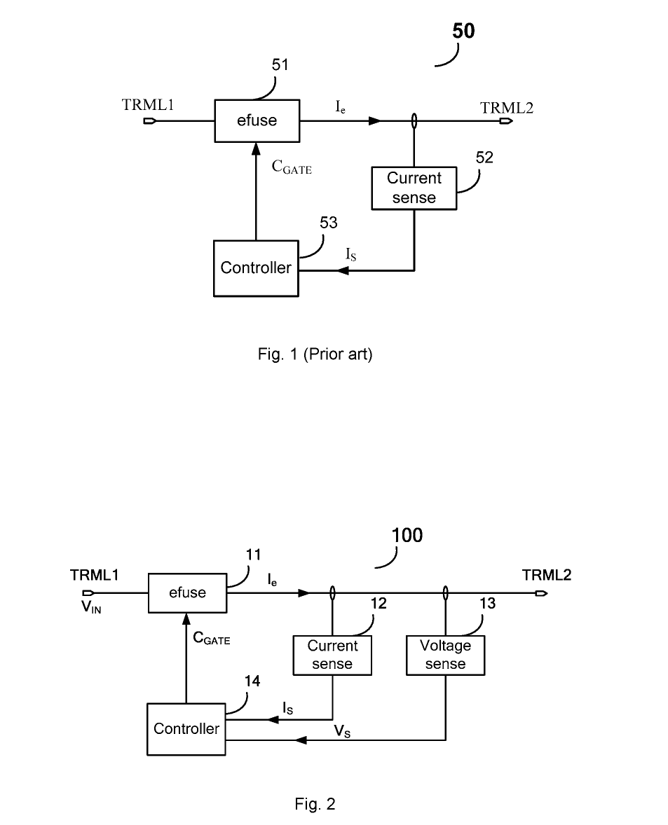

### DETAILED DESCRIPTION

The embodiments of the present invention are described. While the invention will be described in conjunction with various embodiments, it will be understood that this disclosure is not intended to limit the invention to these embodiments. On contrary, the invention is intended to cover alternatives, modifications and equivalents, which may be included within the spirit and scope of the invention as defined by the appended claims. Furthermore, in the following detailed description of the embodiments of the present invention, numerous specific details are set forth in order to provide a thorough understanding of the embodiments of the present invention. However, it will be obvious to one of ordinary skill in the art that without these specific details the embodiments of the present invention may be practiced. In other instance, well-know circuits, materials, and methods have not been described in detail so as not to unnecessarily obscure aspect of the embodiments of the present invention.

FIG. 2 illustrates a power-limit protection circuit 100 with an efuse element in accordance with an embodiment of the present invention. As shown in FIG. 2, the power-limit protection circuit 100 with an efuse element may comprise an efuse element 11, a current sense circuit 12, a voltage sense circuit 13 and a controller 14.

In the exemplary embodiment of FIG. 2, the efuse element 11 may be coupled between a first terminal TRML1 and a second terminal TRML2. A current signal Ie flows through the efuse element 11 from the first terminal TRML1 to the second terminal TRML2. In one embodiment, the first terminal TRML1 may comprise an output terminal of a power supply which may provide a supply voltage V_{IN}, while the second terminal TRML2 may comprise an input terminal of a switching converter which may receive the supply voltage V_{IN}. In another embodiment, the first terminal TRML1 may comprise an output terminal of a switching converter which may provide an output voltage V_{OUT}, while the second terminal TRML2 may comprise an input terminal of a load which may receive the output voltage V_{OUT}. It should be understood for one with ordinary skill in the art that the first terminal TRML1 and the second terminal TRML2 may comprise any terminals of an element, a circuit or a system which may need to be protected.

In the exemplary embodiment of FIG. 2, the current sense circuit 12 may be configured to sense the current signal Ie flowing through the efuse element 11 to generate a sensed current signal I_{S}.

In the exemplary embodiment of FIG. 2, the voltage sense circuit 13 may be configured to sense a voltage signal at the second terminal TRML2 to generate a sensed voltage signal V_{S}.

In the exemplary embodiment of FIG. 2, the controller 14 may be coupled to the current sense circuit 12 to receive the sensed current signal I_{S}, and coupled to the voltage sense circuit 13 to receive the sensed voltage signal V_{S}. The controller 14 is further configured to define a calculated power signal from the sensed current signal I_{S} and the sensed voltage signal V_{S}, and to judge whether the calculated power signal is larger than a predetermined power threshold, and further configured to generate a control signal C_{GATE}. When the calculated power signal is larger than the predetermined power threshold, the control signal C_{GATE} may be configured to control the efuse element 11 to increase an impedance of the efuse element 11 sufficiently to limit the current signal Ie for circuit protection. Thus, the power delivered through the efuse element 11 is limited within the predetermined power threshold. In one embodiment, the control signal C_{GATE} may be a voltage signal for controlling a voltage controlled efuse element 11. In other embodiment, the control signal C_{GATE} may be a current signal for a current controlled efuse element 11.

If the calculated power signal continues to increase, the impedance of efuse element 11 keeps increasing and finally the efuse element 11 enters into a constant-current region (i.e., the impedance of the efuse element 11 is ideally infinite). In one embodiment, the efuse element 11 will get hot when the impedance is increased in order to limit the current Ie. If the temperature of the efuse element 11 exceeds a predetermined threshold, e.g., 150 deg C., the efuse element 11 may be turned off by an over-temperature protection circuit.

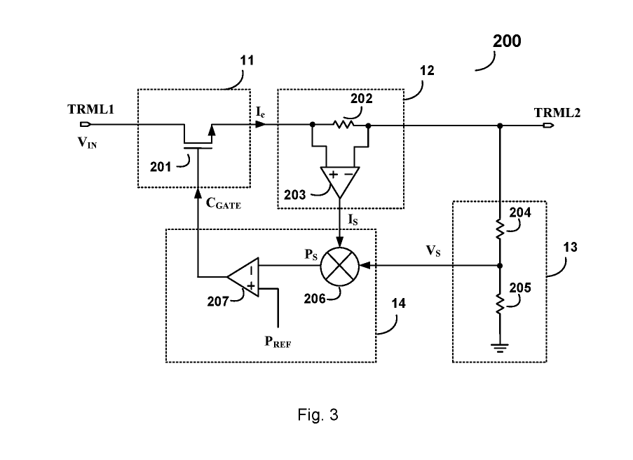

FIG. 3 schematically illustrates a power-limit protection circuit 200 with an efuse element according to an embodiment of the present invention. As shown in FIG. 3, the power-limit protection circuit 200 may also comprise an efuse element 11, a current sense circuit 12, a voltage sense circuit 13 and a controller 14.

In the exemplary embodiment of FIG. 3, the efuse element 11 may comprise a voltage controlled device, for example, a Metal Oxide Semiconductor Field Effect Transistor (MOSFET) 201. MOSFET 201 has a source, a drain and a gate. The drain of the MOSFET 201 may be coupled to the first terminal TRML1, the source of the MOSFET 201 may be coupled to the second terminal TRML2, and the gate of the MOSFET 201 may be coupled to the controller 14 to receive a control signal C_{GATE}. In one embodiment, the first terminal TRML1 may comprise an output terminal of a power supply which may provide a supply voltage V_{IN}, while the second terminal TRML2 may comprise an input terminal of a switching converter which may receive the supply voltage V_{IN}. In another embodiment, the first terminal TRML1 may comprise an output terminal of a switching converter which may provide an output voltage V_{OUT}, while the second terminal TRML2 may comprise an input terminal of a load which may receive the output voltage V_{OUT}. It should be understood that the efuse element 11 of the exemplary embodiment of FIG. 3 may comprise other suitable devices, such as, current controlled devices, or other voltage controlled FETs.

In the exemplary embodiment of FIG. 3, the current sense circuit 12 may comprise a sensing resistor 202 and an amplifier 203. The sensing resistor 202 may be coupled between the source of the MOSFET 201 and the second terminal TRML2. The amplifier 203 may comprise a first input terminal, a second input terminal and an output terminal. The first input terminal of the amplifier 203 may be coupled to a first terminal of the sensing resistor 202. The second input terminal of the amplifier 203 may be coupled to a second terminal of the sensing resistor 202. The amplifier 203 may be configured to provide a sensed current signal I_{S} at its output terminal. In one embodiment, the sensed current signal I_{S} may be indicative of a voltage signal which is equal to a current signal Ie flowing through the MOSFET 201 multiplied by the resistance of the sensing resistor 202.

In the exemplary embodiment of FIG. 3, the voltage sense circuit 13 may comprise a voltage divider coupled between the second terminal TRML2 and a logic ground. The voltage divider may comprise a resistor 204 and a resistor 205 connected in series. A voltage at the common connection of the resistor 204 and the resistor 205 may be provided as the sensed voltage signal V_{S}.

In the exemplary embodiment of FIG. 3, the controller 14 may comprise a multiplier 206 and an error amplifier 207. The multiplier 206 may be configured to receive the sensed current signal I_{S} and the sensed voltage signal V_{S}, and further configured to multiply the sensed current signal I_{S} by the sensed voltage signal V_{S} to generate a calculated power signal P_{S}. The error amplifier 207 may comprise a first input terminal, a second input terminal and an output terminal. The first input terminal of the error amplifier 207 may be configured to receive the calculated power signal P_{S}, the second input terminal of the error amplifier 207 may be configured to receive a predetermined power threshold P_{REF}, and the error amplifier 207 may be configured to compare the calculated power signal P_{S} with the predetermined power threshold P_{REF} and to amplify a difference between the calculated power signal P_{S} and the predetermined power threshold P_{REF} to provide the control signal C_{GATE} at its output terminal. In one embodiment, the first input terminal of the error amplifier 207 is a non-inverting input terminal and the second input terminal of the error amplifier 207 is an inverting input terminal. When the calculated power signal P_{S} is smaller than the predetermined power threshold P_{REF}, the system operates in a normal condition (i.e., no over-power condition occurs). The control signal C_{GATE} may be configured to turn the MOSFET 201 on fully. When the calculated power signal P_{S} is larger than the predetermined power threshold P_{REF}, an over-power condition occurs. The control signal C_{GATE} may be configured to control the MOSFET 201 to operate in a variable resistance region and function to increase an impedance between the source and the drain of the MOSFET 201 so as to limit the current signal Ie for circuit protection. Thus, the power delivered through the MOSFET 201 is limited within the predetermined power threshold P_{REF}. In one embodiment, the control signal C_{GATE} may be a voltage signal for controlling the MOSFET 201.

If the calculated power signal P_{S} continues to increase, the impedance of the MOSFET 201 keeps increasing and finally the MOSFET 201 enters into a constant-current region (i.e., the impedance of the MOSFET 201 is infinite). In one embodiment, the MOSFET 201 will get hot when the resistance is increased in order to limit the current. If the temperature of the MOSFET 201 exceeds a predetermined threshold, e.g., 150 deg C., the MOSFET 201 may be turned off by an over-temperature protection circuit.

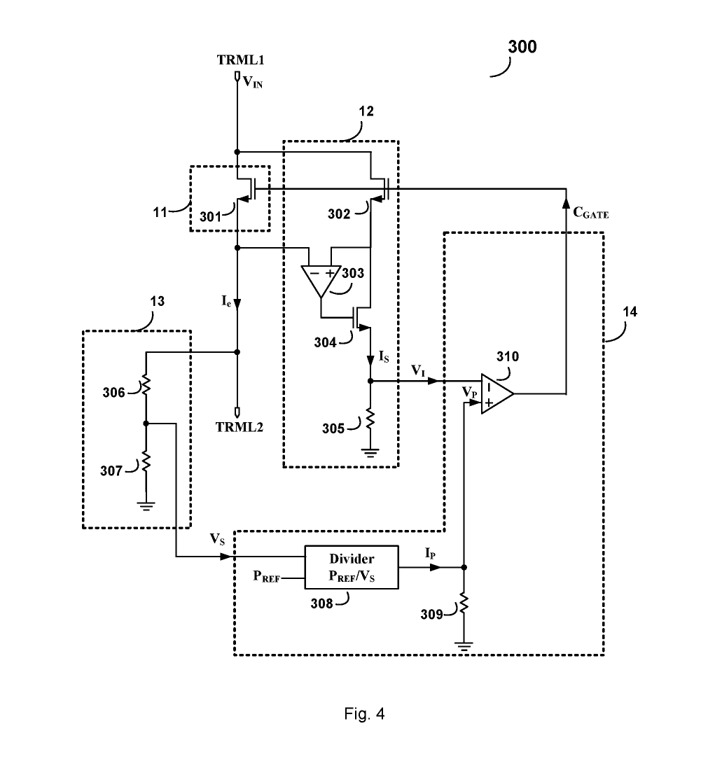

FIG. 4 schematically illustrates a power-limit protection circuit 300 with an efuse element according to an embodiment of the present invention. As shown in FIG. 4, the power-limit protection circuit 300 may also comprise an efuse element 11, a current sense circuit 12, a voltage sense circuit 13 and a controller 14.

In the exemplary embodiment of FIG. 4, the efuse element 11 may comprise a voltage controlled device, for example, a MOSFET 301 having a source, a drain and a gate. The drain of the MOSFET 301 may be coupled to the first terminal TRML1, the source of the MOSFET 301 may be coupled to the second terminal TRML2, and the gate of the MOSFET 301 may be coupled to the controller 14 to receive a control signal C_{GATE}. In one embodiment, the first terminal TRML1 may comprise an output terminal of a power supply which may provide a supply voltage V_{IN}, while the second terminal TRML2 may comprise an input terminal of a switching converter which may receive the supply voltage V_{IN}. In another embodiment, the first terminal TRML1 may comprise an output terminal of a switching converter which may provide an output voltage V_{OUT}, while the second terminal TRML2 may comprise an input terminal of a load which may receive the output voltage V_{OUT}. It should be understood that the efuse element 11 of the exemplary embodiment of FIG. 4 may comprise other suitable devices, e.g., current controlled devices, or other voltage controlled FETs.

In the exemplary embodiment of FIG. 4, the current sense circuit 12 may comprise a transistor 302, an amplifier 303, a transistor 304 and a resistor 305. The transistor 302 having a drain, a source and a gate are connected with the MOSFET 301 in parallel, i.e. the drain of the MOSFET 301 and the drain of the transistor 302 are connected together, and the source of the MOSFET 301 and the source of the transistor 302 are connected together. The amplifier 303 may comprise a first input terminal, a second input terminal and an output terminal. The first input terminal of the amplifier 303 may be coupled to the source of the MOSFET 301, and the second input terminal of the amplifier 303 may be coupled to the source of the transistor 302. The transistor 304 has a drain, a source and a gate. The drain of the transistor 304 may be connected to the source of the transistor 302, the source of the transistor 304 may be connected to the logic ground through the resistor 305, and the gate of the transistor 304 may be connected to the output terminal of the amplifier 303. The amplifier 303 and the transistor 304 may be configured to sense a current signal Ie flowing through the MOSFET 301 so as to generate a sensed current signal I_{S}. A voltage signal V_{I} across the resistor 305 which is indicative of the sensed current signal I_{S} may be finally provided by the current sense circuit 12.

In the exemplary embodiment of FIG. 4, the voltage sensing circuit 13 may comprise a voltage divider coupled between the second terminal TRML2 and the logic ground. The voltage divider may comprise a resistor 306 and a resistor 307 connected in series. A voltage at the common connection of the resistor 306 and the resistor 307 may be provided as the sensed voltage signal V_{S}.

In the exemplary embodiment of FIG. 4, the controller 14 may comprise a divider 308, a resistor 309 and an error amplifier 310.

The divider 308 may comprise a first input terminal, a second input terminal and an output terminal. The first input terminal of the divider 308 may be configured to receive the sensed voltage signal V_{S}, the second input terminal of the divider 308 may be configured to receive a predetermined power threshold P_{REF}, and the divider 308 may be configured to divide the predetermined power threshold P_{REF} by the sensed voltage signal V_{S} to provide a reference current signal I_{P} at its output terminal. The resistor 309 may be connected between the output terminal of divider 308 and a logic ground. A reference voltage signal V_{P} across the resistor 309 may be generated.

The error amplifier 310 may comprise a first input terminal, a second input terminal and an output terminal. The first input terminal of the error amplifier 310 may be configured to receive the voltage signal V_{I}, the second input terminal of the error amplifier 310 may be configured to receive the reference voltage signal V_{P}, and the error amplifier 310 may be configured to compare the voltage signal V_{I} with the reference voltage signal V_{P} so as to provide a control signal C_{GATE} to the gate of the MOSFET 301 and the gate of the transistor 302. In one embodiment, the first input terminal of the error amplifier 310 is an inverting input terminal and the second input terminal of the error amplifier 310 is a non-inverting input terminal. In a no over-power condition, the voltage signal V_{I} is smaller than the reference voltage signal V_{P}. Thus, the control signal C_{GATE} may turn the MOSFET 301 on fully. When an over-power condition occurs, the voltage signal V_{I} is larger than the reference voltage signal V. The control signal C_{GATE} may control the MOSFET 301 to operate in a variable resistance region and function to increase the impedance between the source and the drain of the MOSFET 301 so as to limit the current signal Ie for circuit protection. Thus, the power delivered through the MOSFET 301 is limited within the predetermined power threshold P_{REF}. In an embodiment, the control signal C_{GATE} may be a voltage signal for controlling the MOSFET 301. If the calculated power signal P_{S} continues to increase, the impedance of the MOSFET 301 keeps increasing and the MOSFET 301 finally enters into a constant-current region (i.e., the impedance of the MOSFET 301 is infinite). In one embodiment, the MOSFET 301 will get hot when the resistance is increased in order to limit the current. If the temperature of the MOSFET 301 exceeds a predetermined threshold, e.g., 150 deg C., the MOSFET 301 may be turned off by an over-temperature protection circuit.

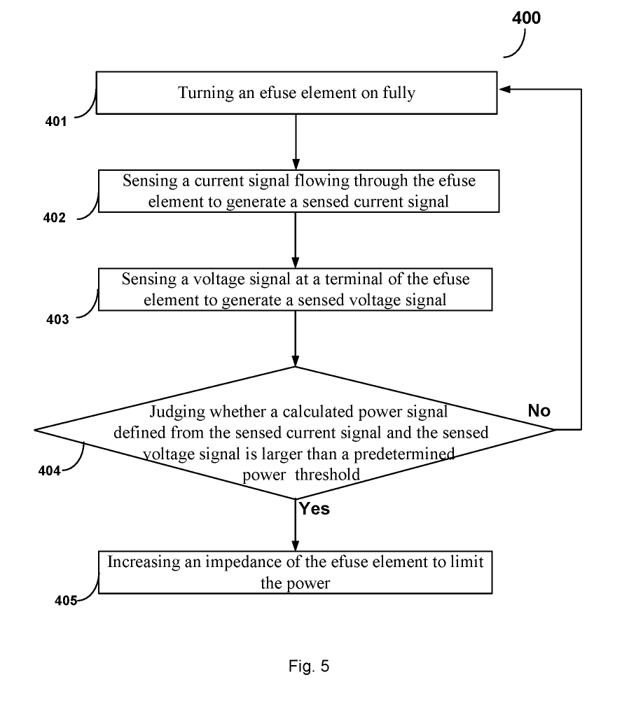

FIG. 5 illustrates a power-limit protection method 400 with an efuse element in accordance with an embodiment of the present invention. The efuse element may be coupled between a first terminal (e.g. the first terminal TRML1 of FIG. 2) and a second terminal (e.g. the second terminal TRML2 of FIG. 2). The protection method 400 may comprise steps 401-405.

In step 401, turning the efuse element on fully. When the efuse element is turned on fully, a current (e.g. the current signal Ie of FIG. 2) may flow through the efuse element from the first terminal to the second terminal. In one embodiment, the first terminal may comprise an output terminal of a power supply which may provide a supply voltage V_{IN}, while the second terminal may comprise an input terminal of a switching converter which may receive the supply voltage V_{IN}. In another embodiment, the first terminal may comprise an output terminal of a switching converter which may provide an output voltage V_{OUT}, while the second terminal may comprise an input terminal of a load which may receive the output voltage V_{OUT}. It should be understood for one with ordinary skill in the art that the first terminal and the second terminal may comprise any terminals of an element, a circuit or a system which may need to be protected.

In step 402, sensing the current signal flowing through the efuse element to generate a sensed current signal. In one embodiment, a current sense circuit may be configured to sense the current signal to generate the sensed current signal.

In step 403, sensing a voltage signal at a terminal of the efuse element to generate a sensed voltage signal. In one embodiment, a voltage sense circuit may be configured to sense the voltage signal to generate the sensed voltage signal.

In step 404, judging whether a calculated power signal defined from the sensed current signal and the sensed voltage signal is larger than a predetermined power threshold. Turn to step 405 once the calculated power signal is larger than the predetermined power threshold, if not, turn to step 401. Repeat the above operation process.

In an embodiment, for example, in the embodiment of FIG. 3, the step of judging whether a calculated power signal defined from the sensed current signal and the sensed voltage signal is larger than a predetermined power threshold may comprise multiplying the sensed current signal by the sensed voltage signal to get the calculated power signal, and comparing the calculated power signal with the predetermined power threshold to judge whether the calculated power signal is larger than the predetermined power threshold.

In another embodiment, for example, in the embodiment of FIG. 4, the step of judging whether a calculated power signal defined from the sensed current signal and the sensed voltage signal is larger than a predetermined power threshold may comprise dividing the predetermined power threshold by the sensed voltage signal to provide a reference current signal, and comparing the sensed current signal with the reference current signal to judge whether the calculated power signal is larger than the predetermined power threshold, wherein when the sensed current signal is larger than the reference current signal indicates that the calculated power signal is larger than the predetermined power threshold. As can be appreciated, other method also can be used for judging whether the calculated power signal is larger than a predetermined power threshold.

In step 405, increasing the impedance of the efuse element to limit the current between the first terminal and the second terminal such that the power delivered through the efuse element is limited within the predetermined power threshold P_{REF}. If the power continues to increase, the impedance of the efuse element keeps increasing and finally enters into a constant-current region (i.e., the impedance of the efuse element is infinite), thus, the power is limited to the predetermined power threshold for protecting the whole system. In one embodiment, the efuse element will get hot when the resistance is increased in order to limit the current. If the temperature of the efuse element exceeds a predetermined threshold, e.g., 150 deg C., the efuse element may be turned off by an over-temperature circuit.

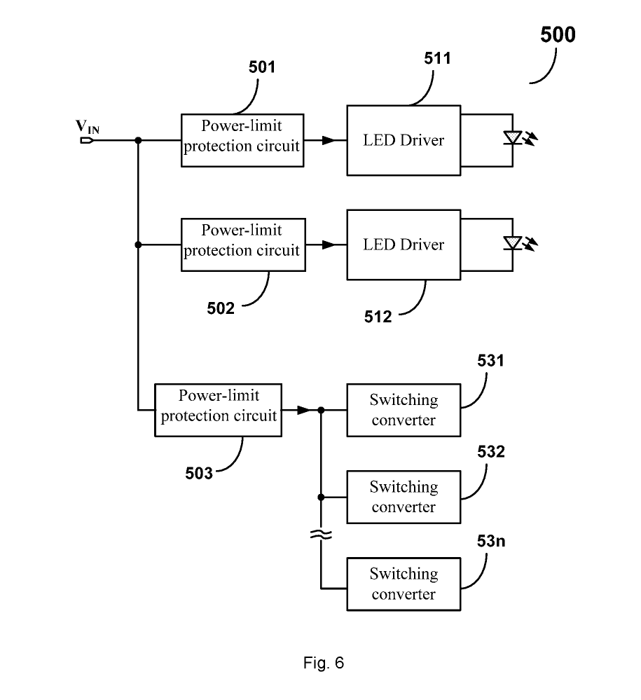

FIG. 6 illustrates a converter system 500 with a plurality of power-limit protection circuits according to an embodiment of the present invention.

As it has been described in FIGS. 2-4, the first terminal TRML1 may comprise an output terminal of a power supply which may provide a supply voltage V_{IN}, while the second terminal TRML2 may comprise an input terminal of a switching converter which may receive the supply voltage V_{IN}. As shown in FIG. 6, converter system 500 may comprise a first LED driver 511, a second LED driver 512, and a plurality of switching converters 531, 532, . . . , 53n. Moreover, the converter system 500 may further comprise three power-limit protection circuits 501, 502, and 503. The power-limit protection circuits 501, 502, and 503 may have the same functions as power-limit protection circuits of FIGS. 2-4.

The power-limit protection circuit 501 is coupled between an input terminal of the converter system 500 which provides a supply voltage V_{IN} and an input terminal of the first LED driver 511. The power-limit protection circuit 501 may be configured to protect the first LED driver 511. When an input power of the first LED driver 511 is larger than a first predetermined input power threshold, the power-limit protection circuit 501 may limit the input power of the first LED driver 511 for circuit protection.

The power-limit protection circuit 502 is coupled between the input terminal of the converter system 500 and an input terminal of the first LED driver 512. The power-limit protection circuit 502 may be configured to protect the second LED driver 512. When an input power of the second LED driver 512 is larger than a second predetermined input power threshold, the power-limit protection circuit 502 may limit the input power of the second LED driver 512 for circuit protection.

The power-limit protection circuit 503 is coupled between the input terminal of the converter system 500 and all of the input terminals of the plurality of switching converters 531, 532, . . . , 53n. The power-limit protection circuit 503 may be configured to protect the plurality of switching converters 531, 532, . . . , 53n. When an input power of the plurality of switching converters 531, 532, . . . , 53n is larger than a third predetermined input power threshold, the power-limit protection circuit 503 may limit the input power of the plurality of switching converters 531, 532, . . . , 53n for circuit protection.

The first predetermined input power threshold, the second input predetermined power threshold and the third input predetermined power threshold can have a same value, or a different value according to the practical applications.

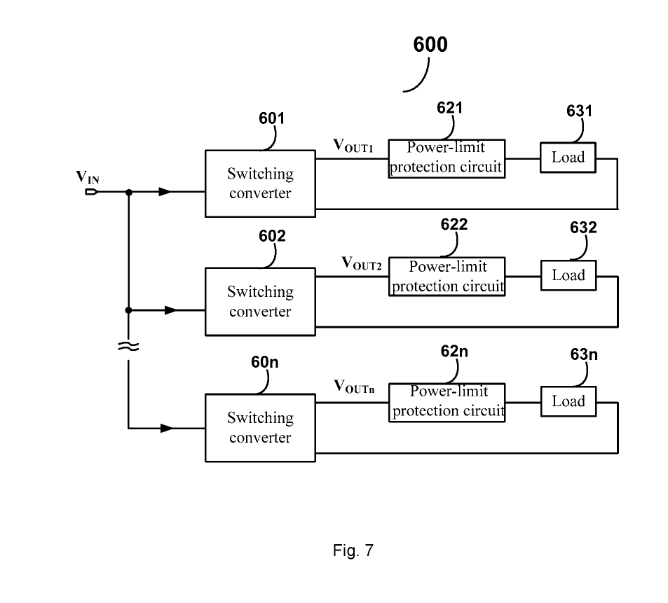

FIG. 7 illustrates a converter system 600 with a plurality of power-limit protection circuits 100 according to an embodiment of the present invention.

As it has been described in FIGS. 2-4, the first terminal TRML1 may comprise an output terminal of a switching converter which may provide an output voltage V_{OUT}, while the second terminal TRML 2 may comprise an input terminal of a load which may receive the output voltage V_{OUT}. As shown in FIG. 7, converter system 600 may comprise a plurality of switching converters 601, 602, . . . , 60n. Moreover, the converter system 600 may further comprise a plurality of power-limit protection circuits 621, 622, . . . , 62n. The plurality of switching converters 601, 602, . . . , 60n may have the same functions as the power-limit protection circuits of FIGS. 2-4.

The power-limit protection circuit 621 is coupled between an output terminal of the switching converter 601 which provides a first output voltage V_{OUT1} and an input terminal of a load 631. The power-limit protection circuit 621 may be configured to protect the switching converter 601. When an output power of the switching converter 601 is larger than a first predetermined output power threshold, the power-limit protection circuit 621 may limit the output power of the switching converter 601 for circuit protection.

The power-limit protection circuit 622 is coupled between an output terminal of the switching converter 602 which provides a second output voltage V_{OUT2} and an input terminal of a load 632. The power-limit protection circuit 622 may be configured to protect the switching converter 602. When an output power of the switching converter 602 is larger than a second predetermined output power threshold, the power-limit protection circuit 622 may be configured to limit the output power of the switching converter 602 for circuit protection.

Similarly, the power-limit protection circuit 62n is coupled between an output terminal of the switching converter 60n which provides an output voltage V_{OUTn} and an input terminal of a load 63n. The power-limit protection circuit 60n may be configured to protect the switching converter 60n. When an output power of the switching converter 60n is larger than a third predetermined output power threshold, the power-limit protection circuit 62n may be configured to limit the output power of the switching converter 602 for circuit protection.

The first predetermined output power threshold, the second output predetermined power threshold and the third output predetermined power threshold can have a same value, or a different value according to the practical application.

It should be noted that the ordinary skill in the art should know that the power-limit protection circuit and the converter system presented in this invention not only limited in a topology, but also in other large applications needed. Similarly, the circuit, controller etc. presented in this invention only used to schematically show as an example.

While various embodiments have been described above, it should be understood that they have been presented by way of example only, and not limitation. Thus, this invention application should not be limited by any of the above-described exemplary embodiments, but should be defined only in accordance with the following claims and their equivalents.

I/We claim:

1. A power-limit protection circuit, comprising:
an efuse element, coupled between a first terminal and a second terminal;
a current sense circuit, configured to sense a current signal flowing through the efuse element to generate a sensed current signal;
a voltage sense circuit, configured to sense a voltage signal at the second terminal to generate a sensed voltage signal; and
a controller, configured to receive the sensed current signal and the sensed voltage signal, to define a calculated power signal from the sensed current signal and the sensed voltage signal, and to judge whether the calculated power signal is larger than a predetermined power threshold, wherein when the calculated power signal is larger than the predetermined power threshold, the controller is configured to increase an impedance of the efuse element to limit the current signal flowing through the efuse element.

2. The power-limit protection circuit of claim 1, wherein the controller comprises:
a multiplier, configured to receive the sensed current signal and the sensed voltage signal, and configured to multiply the sensed current signal by the sensed voltage signal to generate the calculated power signal; and
an error amplifier, configured to receive the calculated power signal and the predetermined power threshold, and further configured to compare the calculated power signal with the predetermined power threshold to provide a control signal to a control terminal of the efuse element, wherein when the calculated power signal is larger than the predetermined power threshold, the control signal is configured to increase the impedance of the efuse element.

3. The power-limit protection circuit of claim 1, wherein the controller comprises:
a divider, configured to receive the sensed voltage signal and the predetermined power threshold, and further configured to divide the predetermined power threshold by the sensed voltage signal to provide a current threshold signal; and
an error amplifier, configured to receive the current threshold signal and the sensed current signal, and further configured to compare the sensed current signal with the current threshold signal to provide a control signal to a control terminal of the efuse element, wherein when the sensed current signal is larger than the current threshold signal, the control signal is configured to increase the impedance of the efuse element.

4. The power-limit protection circuit of claim 1, wherein the predetermined power threshold comprises a predetermined input power threshold, and wherein the first terminal comprises an output terminal of a power supply which is configured to provide a supply voltage, and wherein the second terminal comprises an input terminal of a switching converter which is configured to receive the supply voltage.

5. The power-limit protection circuit of claim 1, wherein the predetermined power threshold comprises a predetermined output power threshold, wherein the first terminal comprises an output terminal of a switching converter which is configured to provide an output voltage, and wherein the second terminal comprises an input terminal of a load which is configured to receive the output voltage.

6. The power-limit protection circuit of claim 1, wherein the efuse element comprises a voltage controlled device.

7. The power-limit protection circuit of claim 1, wherein the efuse element comprises a current controlled device.

8. The power-limit protection circuit of claim 1, wherein the efuse element comprises a MOSFET.

9. The power-limit protection circuit of claim 1, wherein the efuse element is turned off when its temperature exceeds a predetermined temperature threshold.

10. A power-limit protection method with an efuse element, wherein the efuse element is coupled between a first terminal and a second terminal, the power-limit protection method comprising:
turning the efuse element on fully;
sensing a current signal flowing through the efuse element to generate a sensed current signal;
sensing a voltage signal at the first terminal or the second terminal of the efuse element to generate a sensed voltage signal;
judging whether a calculated power signal defined from the sensed current signal and the sensed voltage signal is larger than a predetermined power threshold; and
increasing an impedance of the efuse element to limit the current between the first terminal and the second terminal when the calculated power signal is larger than the predetermined power threshold.

11. The power-limit protection method of claim 10, wherein the step of judging whether a calculated power signal defined from the sensed current signal and the sensed voltage signal is larger than a predetermined power threshold comprises:
multiplying the sensed current signal by the sensed voltage signal to get the calculated power signal; and
comparing the calculated power signal with the predetermined power threshold to judge whether the calculated power signal is larger than the predetermined power threshold.

12. The power-limit protection method of claim 10, wherein the step of judging whether a calculated power signal defined from the sensed current signal and the sensed voltage signal is larger than a predetermined power threshold comprises:
dividing the predetermined power threshold by the sensed voltage signal to get a reference current signal; and
comparing the sensed current signal with the reference current signal to judge whether the calculated power signal is larger than the predetermined power threshold.

13. The power-limit protection method of claim 10, wherein the predetermined power threshold comprises a predetermined input power threshold; and wherein the first terminal comprises an output terminal of a power supply which provides an input voltage, while the second terminal comprises an input terminal of a switching converter which receives the input voltage.

14. The power-limit protection method of claim 10, wherein the predetermined power threshold comprises a predetermined output power threshold; wherein the first terminal comprises an output terminal of a switching converter which provides an output voltage, while the second terminal comprises an input terminal of a load which receives the output voltage.

15. The power-limit protection method of claim 10, wherein the efuse element comprises a voltage controlled device.

16. The power-limit protection method of claim 10, wherein the efuse element comprises a current controlled device.

17. The power-limit protection method of claim 10, wherein the efuse element comprises a MOSFET.

18. The power-limit protection method of claim 10, wherein the efuse element is turned off when its temperature exceeds a predetermined threshold.
